(19) United States
(12) Patent Application Publication
(10) Pub. No.: US 2004/0077142 A1
(43) Pub. Date: Apr. 22, 2004

(54) Atomic layer deposition and plasma treatment method for forming microelectronic capacitor structure with aluminum oxide containing dual dielectric layer

(75) Inventors: Lan-Lin Chao, Taipei (TW); Chia-Shiung Tsai, Hsin-Chu (TW); Chun Chieh Lin, Taichung (TW)

Correspondence Address: TUNG & ASSOCIATES, 838 W. Long Lake Road, Suite 120, Bloomfield Hills, MI, 48302, US

(73) Assignee: Taiwan Semiconductor Manufacturing Co., Ltd.

(21) Appl. No.: 10/273,046

(22) Filed: Oct. 17, 2002

(51) Int. Cl. H01L 21/8242; H01L 21/20

(52) U.S. Cl. 438/253; 438/255; 438/398

(57) ABSTRACT

Within a method for forming a capacitor within a microelectronic fabrication, there is employed a bilayer capacitor dielectric layer formed in part of an aluminum oxide dielectric material deposited employing an atomic layer deposition (ALD) method, and subsequently plasma treated. The aluminum oxide dielectric material deposited employing the atomic layer deposition (ALD) method and subsequently plasma treated provides for enhanced performance of the capacitor.

### BACKGROUND OF THE INVENTION

1. Field of the Invention

The present invention relates generally to capacitor structures, as employed within microelectronic fabrications. More particularly, the present invention relates to capacitor structures with enhanced performance, as employed within microelectronic fabrications.

2. Description of the Related Art

Microelectronic fabrications are formed from microelectronic substrates over which are formed patterned microelectronic conductor layers which are separated by microelectronic dielectric layers.

In addition to the fabrication and use of transistors, resistors and diodes within microelectronic fabrications, it is also common in the art of microelectronic fabrication to fabricate and use capacitors within microelectronic fabrications. Capacitors within microelectronic fabrications may serve functions including but not limited to: (1) charge storage functions within microelectronic fabrications such as dynamic random access memory (DRAM) microelectronic fabrications; as well as (2) operational functions within various types of circuits within various types of microelectronic fabrications.

While capacitors are thus clearly desirable in the art of microelectronic fabrication and often essential in the art of microelectronic fabrication, capacitors are nonetheless not entirely without problems in the art of microelectronic fabrication.

In that regard, it is often difficult in the art of microelectronic fabrication to fabricate within microelectronic fabrications capacitors with enhanced performance, in particular within decreased microelectronic fabrication substrate area.

It is thus desirable in the art of microelectronic fabrication to form within microelectronic fabrications capacitors with enhanced performance.

It is towards the foregoing object that the present invention is directed.

Various capacitor structures having desirable properties, and methods for fabrication thereof, have been disclosed in the art of microelectronic fabrication.

Included among the capacitor structures and methods for fabrication thereof, but not limiting among the capacitor structures and methods for fabrication thereof, are capacitor structures and methods for fabrication thereof disclosed within: (1) Howard, in U.S. Pat. No. 4,437,139 (a capacitor structure having formed therein a dual dielectric layer having a comparatively high dielectric constant, wherein at least one dielectric layer within the dual dielectric layer is laser annealed to provide the comparatively high dielectric constant); (2) Howard et al., in U.S. Pat. No. 4,471,405 (a capacitor structure having formed therein a bottom electrode formed as a dual layer with a intermetallic metal forming metal); (3) Shinriki et al., in U.S. Pat. No. 4,937,650 (an additional capacitor structure having formed therein a dual dielectric layer, but in part formed intrinsically); (4) Emesh et al., in U.S. Pat. No. 5,452,178 (a capacitor structure having formed therein a dual dielectric layer, one layer of which is formed as a spacer layer); (5) Gates et al., in U.S. Pat. No. 6,203,613 (an atomic layer deposition (ALD) method which may be employed for forming capacitor dielectric layers within capacitor structures); and (6) Quek et al., in U.S. Pat. No. 6,261,917 (a capacitor structure having formed therein a dielectric layer formed in-situ while employing a photo-oxidation method).

Desirable in the art of microelectronic fabrication are additional methods and materials which may be employed for forming within microelectronic fabrications capacitor structures with enhanced performance.

It is towards the foregoing object that the present invention is directed.

### SUMMARY OF THE INVENTION

A first object of the present invention is to provide a method for forming a capacitor structure within a microelectronic fabrication.

A second object of the present invention is to provide a method in accord with the first object of the present invention, wherein the capacitor structure is formed with enhanced performance.

A third object of the present invention is to provide a method in accord with the first object of the present invention and the second object of the present invention, wherein the method is readily commercially implemented.

In accord with the objects of the present invention, there is provided by the present invention a method for forming a capacitor structure within a microelectronic fabrication.

To practice the method of the present invention, there is first provided a substrate. There is then formed over the substrate a first capacitor plate layer. There is then formed upon the first capacitor plate layer a capacitor dielectric layer comprising: (1) a first capacitor dielectric sub-layer formed of an aluminum oxide dielectric material formed employing an atomic layer deposition method, where the first capacitor dielectric sub-layer is plasma treated; and (2) a second capacitor dielectric sub-layer formed of other than the aluminum oxide dielectric material, and preferably a tantalum oxide dielectric material. Finally, there is then formed upon the capacitor dielectric layer a second capacitor plate layer.

The present invention provides a method for forming a capacitor structure within a microelectronic fabrication, wherein the capacitor structure is formed with enhanced performance.

The present invention realizes the foregoing object by forming within the capacitor structure a capacitor dielectric layer comprising: (1) a first capacitor dielectric sub-layer formed of an aluminum oxide dielectric material formed employing an atomic layer deposition method, where the first capacitor dielectric sub-layer is plasma treated; and (2) a second capacitor dielectric sub-layer formed of other than the aluminum oxide dielectric material.

The method of the present invention is readily commercially implemented.

The present invention employs methods and materials as are otherwise generally known in the art of microelectronic fabrication, but employed within the context of a specific process ordering to provide the present invention. Since it is thus at least in part a specific process ordering which provides at least in part the present invention, rather than the existence of methods and materials which provides the present invention, the method of the present invention is readily commercially implemented.

### BRIEF DESCRIPTION OF THE DRAWINGS

The objects, features and advantages of the present invention are understood within the context of the Description of the Preferred Embodiment, as set forth below. The Description of the Preferred Embodiment is understood within the context of the accompanying drawings, which form a material part of this disclosure, wherein:

FIG. 1, FIG. 2, FIG. 3, FIG. 4, FIG. 5 and FIG. 6 shown a series of schematic cross-sectional diagrams illustrating the results of progressive stages of forming, in accord with a preferred embodiment of the present invention, a storage capacitor within a semiconductor integrated circuit microelectronic fabrication.

### DESCRIPTION OF THE PREFERRED EMBODIMENT

The present invention provides a method for forming a capacitor structure within a microelectronic fabrication, wherein the capacitor structure is formed with enhanced performance.

The present invention realizes the foregoing object by forming within the capacitor structure a capacitor dielectric layer comprising: (1) a first capacitor dielectric sub-layer formed of an aluminum oxide dielectric material formed employing an atomic layer deposition method, where the first capacitor dielectric sub-layer is plasma treated; and (2) a second capacitor dielectric sub-layer formed of other than the aluminum oxide dielectric material.

The preferred embodiment of the present invention illustrates the present invention within the context of forming, with enhanced performance, a storage capacitor within a dynamic random access memory (DRAM) cell within a semiconductor integrated circuit microelectronic fabrication. However, the present invention may be employed for forming capacitors including but not limited to storage capacitors and active circuit capacitors within microelectronic fabrications including but not limited to integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

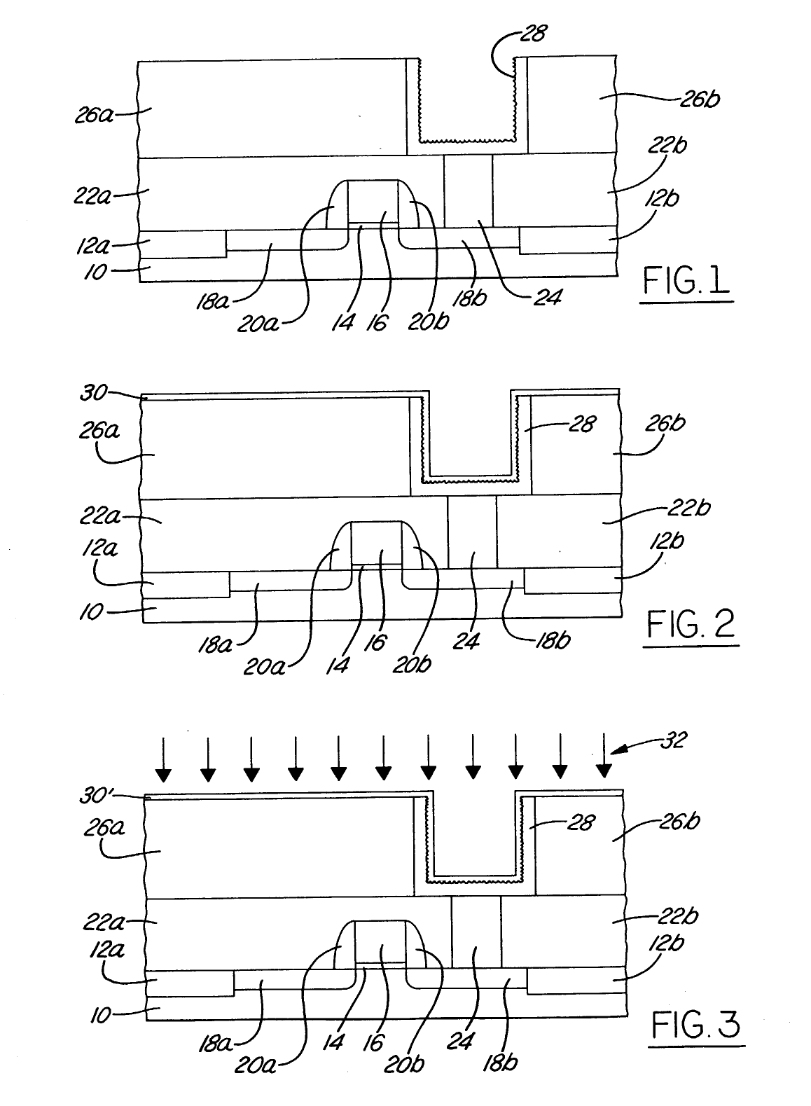

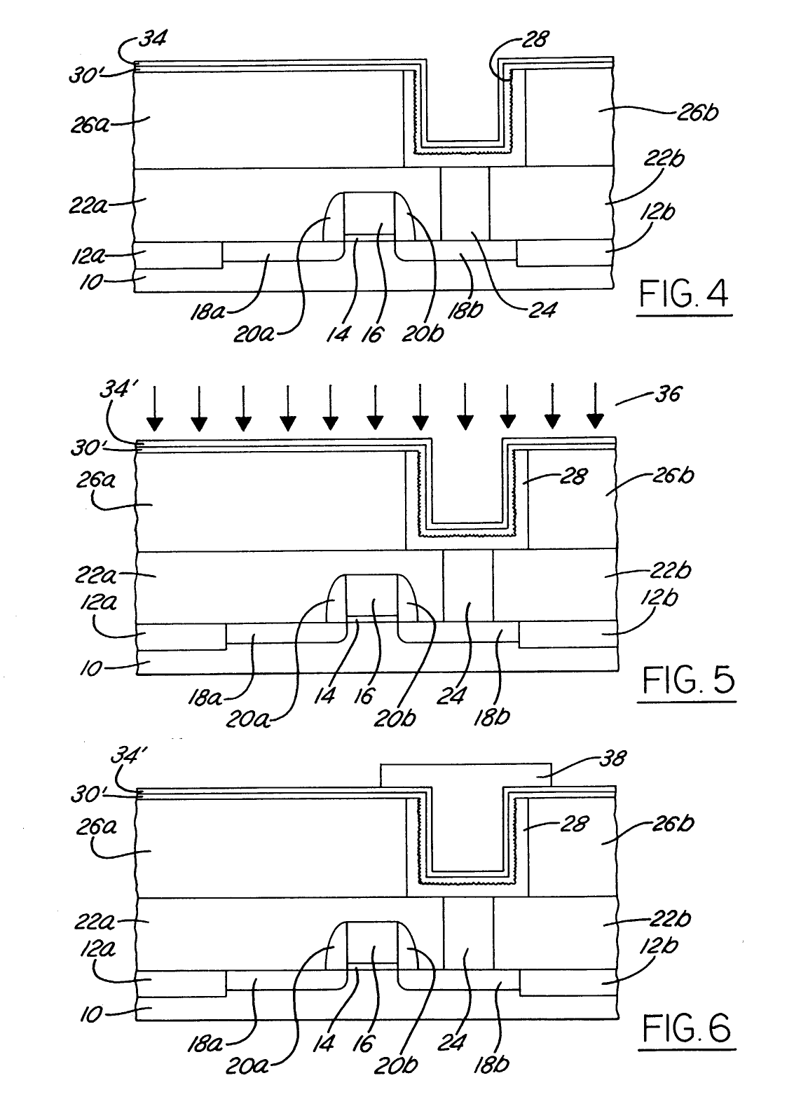

Referring now to FIG. 1 to FIG. 6, there is shown a series of schematic cross-sectional diagrams illustrating the results of progressive stages of forming, in accord with a preferred embodiment of the present invention, a storage capacitor within a dynamic random access memory (DRAM) cell within a semiconductor integrated circuit microelectronic fabrication.

Shown in FIG. 1 is a schematic cross-sectional diagram of the semiconductor integrated circuit microelectronic fabrication at an early stage in its fabrication in accord with the preferred embodiment of the present invention.

Shown in FIG. 1, in a first instance, is a semiconductor substrate 10 having formed therein a pair of isolation regions 12a and 12b which define an active region of the semiconductor substrate 10.

Within the preferred embodiment of the present invention, the semiconductor substrate 10 is typically and preferably a (100) silicon semiconductor substrate, although semiconductor substrates of alternate compositions and crystallographic orientations may also be employed when fabricating a capacitor structure in accord with the present invention. Similarly, although the preferred embodiment of the present invention illustrates the pair of isolation regions 12a and 12b as a pair of shallow trench isolation (STI) regions, the present invention may also be practiced when the pair of isolation regions 12a and 12b is formed as isolation regions selected from the group including but not limited to local oxidation of silicon (LOCOS) isolation regions, shallow trench isolation (STI) regions and deep trench isolation regions.

Shown also within the schematic cross-sectional diagram of FIG. 1, and formed within and upon the active region of the semiconductor substrate 10 as defined by the pair of isolation regions 12a and 12b, is a series of structures which comprises a field effect transistor (FET) device. As is illustrated within the schematic cross-sectional diagram of FIG. 1, the series of structures comprises: (1) a gate dielectric layer 14 formed upon the active region of the semiconductor substrate 10; (2) a gate electrode 16 formed and aligned upon the gate dielectric layer 14; (3) a pair of source/drain regions 18a and 18b formed into the active region of the semiconductor substrate 10 and separated by the gate electrode 16 and the gate dielectric layer 14; and (4) a pair of spacer layers 20a and 20b formed adjoining a pair of opposite sidewalls of the gate electrode 16 and the gate dielectric layer 14.

Within the preferred embodiment of the present invention, each of the foregoing series of structures which forms the field effect transistor (FET) device may be formed employing methods and materials as are conventional in the art of semiconductor integrated circuit microelectronic fabrication. Typically and preferably, the gate dielectric layer 14 is formed at least in part of a silicon oxide dielectric material formed to a thickness of from about 60 to about 90 angstroms. Typically and preferably, the gate electrode 16 is formed at least in part of a doped polysilicon material (having a dopant concentration of from about 10²⁰ to about 10²¹ dopant atoms per cubic centimeter) formed to a thickness of from about 800 to about 1000 angstroms. Typically and preferably, the pair of source/drain regions 18a and 18b is formed while employing an ion implantation method at an ion implantation dose of from about 1014 to about 1016 ions per square centimeter and an ion implantation energy of from about 15 KeV to about 25 KeV while employing the gate electrode 16 as a mask, to provide the pair of source/drain regions 18a and 18b of dopant concentration. Finally, typically and preferably, the pair of spacer layers 20a and 20b is formed employing an anisotropic etching of a blanket spacer material layer.

Shown also within the schematic cross-sectional diagram of FIG. 1, and formed passivating the field effect transistor (FET) device is a pair of patterned planarized pre-metal dielectric (PMD) layers 22a and 22b which define a first aperture, at the bottom of which is exposed a portion of the source/drain region 18b. Shown also within the schematic cross-sectional diagram of FIG. 1 and formed into the first aperture is a conductor contact stud 24.

Within the preferred embodiment of the present invention with respect to the pair of patterned planarized pre-metal dielectric (PMD) layers 22a and 22b, the pair of patterned planarized pre-metal dielectric (PMD) layers 22a and 22b is typically and preferably formed at least in part of a silicon oxide dielectric material, preferably with an etch stop material formed upon its upper surface. Typically and preferably, the pair of patterned planarized pre-metal dielectric (PMD) layers 22a and 22b is formed to define the first aperture of linewidth, which leaves exposed the portion of the source/drain region 18b.

Within the preferred embodiment of the present invention with respect to the conductor contact stud 24, and although the conductor contact stud 24 may be formed employing any of several conductor materials (i.e., metals, metal alloys, doped polysilicon and polycides) formed employing any of several methods, for the preferred embodiment of the present invention the conductor contact stud 24 is typically and preferably formed of at least in part of a doped polysilicon material or a tungsten material.

In addition, there is also shown within the schematic cross-sectional diagram of FIG. 1, and formed upon the pair of patterned planarized pre-metal dielectric (PMD) layers 22a and 22b, a pair of patterned capacitor node dielectric layers 26a and 26b which define a second aperture, at the bottom of which is exposed the conductor contact stud 24. Finally, there is also shown within the schematic cross-sectional diagram of FIG. 1, and formed conformally within the second aperture and contacting the conductor contact stud 24, a capacitor node layer 28.

Within the preferred embodiment of the present invention with respect to the pair of patterned capacitor node dielectric layers 26a and 26b, the pair of patterned capacitor node dielectric layers 26a and 26b is typically and preferably formed employing methods and materials generally analogous to the methods and materials as are employed for forming the pair of patterned planarized pre-metal dielectric (PMD) layers 22a and 22b. Typically and preferably, each of the pair of patterned capacitor node dielectric layers 26a and 26b is formed to a thickness of from about 12000 to about 25000 angstroms to define the second aperture of linewidth from about 0.13 to about 0.18 microns.

Similarly, within the preferred embodiment of the present invention with respect to the capacitor node layer 28, the capacitor node layer 28 is typically and preferably formed of a hemispherical grained (HSG) polysilicon material which provides the capacitor node layer 28 with enhanced surface area. To form the capacitor node layer 28 of the hemispherical grained (HSG) polysilicon material, there is employed a chemical vapor deposition (CVD) method which employs: (1) a reactor chamber pressure; (2) no radio frequency source power or bias power; (3) a substrate (and overlying layers) temperature of from about 550 to about 575 degrees centigrade; and (4) a silane silicon source material flow rate of from about 5 to about 50 standard cubic centimeters per minute (sccm) along with an appropriate intrinsic dopant source material. Typically and preferably, the capacitor node layer 28 is formed to a thickness of from about 200 to about 500 angstroms incident to chemical mechanical polish planarizing a corresponding blanket capacitor node layer. Typically and preferably, subsequent to such chemical mechanical polish (CMP) planarizing to form the capacitor node layer 28 from the corresponding blanket capacitor node layer, the capacitor node layer 28 is cleaned via immersion within a 100:1 dilute hydrofluoric (DHF) solution at a temperature of from about 20 to about 50 degrees centigrade for a time period of from about 0.5 to about 3 minutes to provide an optimal surface for additional processing within the context of the preferred embodiment of the present invention.

Referring now to FIG. 2, there is shown a schematic cross-sectional diagram illustrating the results of further processing of the semiconductor integrated circuit microelectronic fabrication whose schematic cross-sectional diagram is illustrated in FIG. 1.

Shown in FIG. 2 is a schematic cross-sectional diagram of a semiconductor integrated circuit microelectronic fabrication otherwise equivalent to the semiconductor integrated circuit microelectronic fabrication whose schematic cross-sectional diagram is illustrated in FIG. 1, but wherein there is formed upon exposed portions of the pair of patterned capacitor node dielectric layers 26a and 26b and the capacitor node layer 28 a blanket first capacitor dielectric layer.

Within the preferred embodiment of the present invention, the blanket first capacitor dielectric layer 30 is formed of an aluminum oxide dielectric material deposited employing an atomic layer deposition (ALD) method generally in accord with the atomic layer deposition (ALD) methods as disclosed within Gates et al., as cited within the Description of the Related Art, the disclosures of all of which related art references are incorporated herein fully by reference. As is understood by a person skilled in the art, such atomic layer deposition (ALD) methods provide for alternatively and sequentially: (1) depositing a monolayer of an aluminum containing precursor source material; and (2) oxidizing the monolayer of the aluminum containing material with an oxidant source material, both of which process steps may be undertaken at comparatively low temperatures of from about 300 to about 500 degrees centigrade.

Within the present invention, the atomic layer deposition (ALD) method also preferably employs: (1) a reactor chamber pressure of from about 0.1 to about 10 torr; (2) no radio frequency source power or bias power; (3) a substrate (and overlying layers) temperature of from about 300 to about 500 degrees centigrade; (3) an aluminum tetrachloride aluminum precursor source material; and (4) an oxygen oxidant source material at a flow rate of from about 100 to about 500 standard cubic centimeters per minute (sccm).

Within the preferred embodiment of the present invention, the blanket first capacitor dielectric layer 30 is typically and preferably formed to a thickness of from about 10 to about 20 angstroms. Similarly, the blanket first capacitor dielectric layer 30 is formed employing the atomic layer deposition (ALD) method insofar as the atomic layer deposition (ALD) method provides enhanced gap filling characteristics with respect to the capacitor node layer 28 when formed of the hemispherical grained (HSG) polysilicon material. In accord with the above, the atomic layer deposition (ALD) method also advantageously provides a generally reduced deposition temperature.

Referring now to FIG. 3, there is shown a schematic cross-sectional diagram illustrating the results of further processing of the semiconductor integrated circuit microelectronic fabrication whose schematic cross-sectional diagram is illustrated in FIG. 2.

Shown in FIG. 3 is a schematic cross-sectional diagram of a semiconductor integrated circuit microelectronic fabrication otherwise equivalent to the semiconductor integrated circuit microelectronic fabrication whose schematic cross-sectional diagram is illustrated in FIG. 2, but wherein the blanket first capacitor dielectric layer 30 has been treated with a first plasma 32 to form therefrom a plasma treated blanket first capacitor dielectric layer 30.

Within the preferred embodiment of the present invention, the first plasma 32 may comprise an oxidizing gas, a nitriding gas or both an oxidizing and a nitriding gas (either separate or intrinsic) to provide the plasma treated blanket first capacitor dielectric layer 30′ as further oxidized and/or nitrided in comparison with the blanket first capacitor dielectric layer 30. Such further oxidation or nitridation provides, within the context of the present invention, the plasma treated blanket first capacitor dielectric layer 30′ with optimal leakage barrier dielectric properties in comparison with the blanket first capacitor dielectric layer 30.

Typically and preferably, the first plasma 32 employs at least one oxidizing and/or nitriding gas selected from the group including but not limited to oxygen, ozone, nitrogen, nitrous oxide, nitric oxide and ammonia. Typically and preferably, the first plasma 32 also employs: (1) a reactor chamber pressure of from about 1 to about 5 torr; (2) a source radio frequency power of from about 1000 to about 3000 watts, without a bias power; (3) a substrate (and overlying layers) temperature of from about 350 to about 500 degrees centigrade; (4) at least one oxidant or nitridant gas at a flow rate of from about 1000 to about 5000 standard cubic centimeters per minute (sccm).

Referring now to FIG. 4, there is shown a schematic cross-sectional diagram illustrating the results of further processing of the semiconductor integrated circuit microelectronic fabrication whose schematic cross-sectional diagram is illustrated in FIG. 3.

Shown in FIG. 4 is a schematic cross-sectional diagram of a semiconductor integrated circuit microelectronic fabrication otherwise equivalent to the semiconductor integrated circuit microelectronic fabrication whose schematic cross-sectional diagram is illustrated in FIG. 3, but wherein there is formed upon the plasma treated blanket first capacitor layer 30′ a blanket second capacitor dielectric layer 34.

Within the preferred embodiment of the present invention, the blanket second capacitor dielectric layer 34 may be formed from any of several capacitor dielectric materials as are known in the art, other than aluminum oxide capacitor dielectric materials. Such capacitor dielectric materials are disclosed in greater detail within the references cited within the Description of the Related Art. Typically and preferably, however, the blanket second capacitor dielectric layer 34 is formed of a tantalum oxide dielectric material, which may be formed employing any of several methods, including but not limited to traditional chemical vapor deposition (CVD) methods (which employ a simultaneous mixing of reactants and delivery to a substrate) and atomic layer deposition (ALD) methods (which as noted above digitally, sequentially and repetitively employ a metal precursor material deposition followed by an in-situ oxidation). Typically and preferably, the blanket second capacitor dielectric layer 34 is formed to a thickness of from about 50 to about 100 angstroms.

Referring now to FIG. 5, there is shown a schematic cross-sectional diagram illustrating the results of further processing of the semiconductor integrated circuit microelectronic fabrication whose schematic cross-sectional diagram is illustrated in FIG. 4.

Shown in FIG. 5 is a schematic cross-sectional diagram of a semiconductor integrated circuit microelectronic fabrication otherwise equivalent to the semiconductor integrated circuit microelectronic fabrication whose schematic cross-sectional diagram is illustrated in FIG. 4, but wherein the blanket second capacitor dielectric layer 34 has been treated with a second plasma 36 to form a plasma treated blanket second capacitor dielectric layer 34′.

Within the preferred embodiment of the present invention, the second plasma 36 typically and preferably employs materials and process conditions analogous or equivalent to the materials and process conditions as are employed when providing the first plasma 32 as illustrated within the schematic cross-sectional diagram of FIG. 3.

Referring now to FIG. 6, there is shown a schematic cross-sectional diagram illustrating the results of further processing of the semiconductor integrated circuit microelectronic fabrication whose schematic cross-sectional diagram is illustrated in FIG. 5.

Shown in FIG. 6 is a schematic cross-sectional diagram of a semiconductor integrated circuit microelectronic fabrication otherwise equivalent to the semiconductor integrated circuit microelectronic fabrication whose schematic cross-sectional diagram is illustrated in FIG. 5, but wherein there is formed upon the plasma treated blanket second capacitor dielectric layer 34′ a patterned capacitor plate layer 38.

Within the preferred embodiment of the present invention, the patterned capacitor plate layer 38 may be formed employing methods and materials as are conventional or unconventional in the art of microelectronic fabrication.

Typically and preferably the patterned capacitor plate layer 38 is formed of a titanium nitride or polysilicon material formed to a thickness of from about 200 to about 500 angstroms.

As is understood by a person skilled in the art, although the preferred embodiment of the present invention illustrates the present invention within the context of first forming a blanket first capacitor dielectric layer formed of an aluminum oxide dielectric material formed employing an atomic layer deposition (ALD) method and plasma treating the blanket first capacitor dielectric layer prior to forming thereupon a blanket second capacitor dielectric layer, preferably formed of a tantalum oxide dielectric material, the present invention also contemplates a reverse ordering of for forming a the foregoing layers in conjunction with their plasma treatments.

Upon forming the semiconductor integrated circuit microelectronic fabrication whose schematic cross-sectional diagram is illustrated in FIG. 6, there is formed a semiconductor integrated circuit microelectronic fabrication in accord with the preferred embodiment of the present invention. The semiconductor integrated circuit microelectronic fabrication has formed therein a storage capacitor formed with enhanced performance insofar as the storage capacitor has formed therein a capacitor dielectric layer formed as a bilayer, one layer of which is formed of an aluminum oxide dielectric material deposited employing an atomic layer deposition (ALD) method, and subsequently plasma treated.

As is further understood by a person skilled in the art, the preferred embodiment of the present invention is illustrative of the present invention rather than limiting of the present invention. Revisions and modifications may be made to methods, materials, structures and dimensions employed for fabricating a semiconductor integrated circuit microelectronic fabrication in accord with the preferred embodiment of the present invention while still providing a microelectronic fabrication fabricated in accord with the present invention, further in accord with the appended claims.

What is claimed is:

1. A method for fabricating a capacitor comprising:
providing a substrate;
forming over the substrate a first capacitor plate layer;
forming upon the first capacitor plate layer a capacitor dielectric layer comprising:
a first capacitor dielectric sub-layer formed of an aluminum oxide dielectric material formed employing an atomic layer deposition method, the first capacitor dielectric sub-layer being plasma treated; and
a second capacitor dielectric sub-layer formed of other than the aluminum oxide dielectric material; and
forming upon the capacitor dielectric layer a second capacitor plate layer.

2. The method of claim 1 wherein the substrate is employed within a microelectronic fabrication selected from the group consisting of integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

3. The method of claim 1 wherein the first capacitor plate layer is formed of a hemispherical grained polysilicon material.

4. The method of claim 1 wherein the first capacitor dielectric sub-layer is formed before the second capacitor dielectric sublayer.

5. The method of claim 1 wherein the second capacitor dielectric sub-layer is formed before the first capacitor dielectric sublayer.

6. The method of claim 1 wherein the first capacitor dielectric sub-layer is formed to a thickness of from about 10 to about 20 angstroms.

7. The method of claim 1 wherein the second capacitor dielectric sub-layer is formed to a thickness of from about 50 to about 100 angstroms.

8. The method of claim 1 wherein the second capacitor dielectric sub-layer is formed of a tantalum oxide dielectric material.

9. A method for fabricating a capacitor comprising:
providing a semiconductor substrate;
forming over the semiconductor substrate a first capacitor plate layer;
forming upon the first capacitor plate layer a capacitor dielectric layer comprising:
a first capacitor dielectric sub-layer formed of an aluminum oxide dielectric material formed employing an atomic layer deposition method, the first capacitor dielectric sub-layer being plasma treated; and
a second capacitor dielectric sub-layer formed of other than the aluminum oxide dielectric material; and
forming upon the capacitor dielectric layer a second capacitor plate layer.

10. The method of claim 9 wherein the first capacitor plate layer is formed of a hemispherical grained polysilicon material.

11. The method of claim 9 wherein the first capacitor dielectric sub-layer is formed before the second capacitor dielectric sublayer.

12. The method of claim 9 wherein the second capacitor dielectric sub-layer is formed before the first capacitor dielectric sublayer.

13. The method of claim 9 wherein the first capacitor dielectric sub-layer is formed to a thickness of from about 10 to about 20 angstroms.

14. The method of claim 9 wherein the second capacitor dielectric sub-layer is formed to a thickness of from about 50 to about 100 angstroms.

15. The method of claim 9 wherein the second capacitor dielectric sub-layer is formed of a tantalum oxide dielectric material.
